(19) United States
(12) Patent Application Publication
(10) Pub. No.: US 2026/0096178 A1
(43) Pub. Date: Apr. 2, 2026

(54) TRANSISTORS AND SEMICONDUCTOR DEVICES INCLUDING THE SAME

(71) Applicant: Samsung Electronics Co., Ltd., Suwon-si (KR)

(72) Inventor: Donggun Kim, Suwon-si (KR)

(21) Appl. No.: 19/279,630

(22) Filed: Jul. 24, 2025

(30) Foreign Application Priority Data
Oct. 2, 2024 (KR) 10-2024-0133622

(51) Int. Cl. H10D 64/27; H10D 84/01; H10D 84/83

(52) U.S. Cl. CPC H10D 64/517; H10D 64/514; H10D 84/014; H10D 84/0142; H10D 84/83135; H10D 84/83138

(57) ABSTRACT

A transistor may include a gate structure on a substrate, the gate structure including a first gate dielectric pattern including a first metal oxide. A gate electrode includes a lower portion with a second metal oxide doped with tetravalent and pentavalent elements or with a metal oxynitride doped with the tetravalent and pentavalent elements. The gate electrode includes an upper portion on the lower portion with a metal doped with the tetravalent and pentavalent elements or a metal nitride doped with the tetravalent and pentavalent elements and a source/drain region at an upper portion of the substrate adjacent to the gate structure.

### CROSS-REFERENCE TO RELATED APPLICATION

This application claims priority under 35 U.S.C. § 119 to Korean Patent Application No. 10-2024-0133622 filed on Oct. 2, 2024, in the Korean Intellectual Property Office, the disclosure of which is hereby incorporated by reference in its entirety.

### DISCUSSION OF RELATED ART

A high-K metal gate structure may include a gate dielectric pattern including a high-K dielectric material and a gate electrode including a metal that are sequentially stacked. The high-K dielectric material generally includes an oxide, so that oxygen in the oxide may diffuse into the metal included in the gate electrode contacting the oxide to form a metal oxide, which reduces the capacitance of the gate electrode. Thus, a method of preventing this problem is needed.

### SUMMARY

Example implementations provide a transistor having improved characteristics.

Example implementations provide a semiconductor device having improved characteristics.

According to example implementations, there is provided a transistor. The transistor may include a gate structure on a substrate, the gate structure including a first gate dielectric pattern including a first metal oxide, a gate electrode comprising a lower portion including a second metal oxide doped with tetravalent and pentavalent elements or a metal oxynitride doped with the tetravalent and pentavalent elements and an upper portion on the lower portion including a metal doped with the tetravalent and pentavalent elements or a metal nitride doped with the tetravalent and pentavalent elements and a source/drain region at an upper portion of the substrate adjacent to the gate structure.

According to example implementations, there is provided a transistor. The transistor may include a gate structure including a gate interface pattern, a first gate dielectric pattern, a second gate dielectric pattern and a gate electrode sequentially stacked on a substrate and a source/drain region at an upper portion of the substrate adjacent to the gate structure, wherein the gate interface pattern includes silicon oxide, each of the first and second gate dielectric patterns includes a high-K material, the gate electrode includes a metal or a metal nitride doped with tetravalent and pentavalent elements, and a concentration of the tetravalent and pentavalent elements in the gate electrode decreases along a vertical direction substantially perpendicular to an upper surface of the substrate as a distance from the upper surface of the substrate increases.

According to example implementations, there is provided a semiconductor device. The semiconductor device may include a first transistor including a first gate structure including a first gate interface pattern, a first gate dielectric pattern and a first gate electrode sequentially stacked on a first region of a substrate including the first region and a second region and a first source/drain region at an upper portion of the substrate adjacent to the first gate structure, an epitaxial layer on the second region of the substrate and a second transistor including a second gate structure including a second gate interface pattern, a second gate dielectric pattern, a second gate electrode, a third gate dielectric pattern and a third gate electrode sequentially stacked on the epitaxial layer and a second source/drain region at an upper portion of the epitaxial layer adjacent to the second gate structure, wherein each of the first and third gate electrodes includes a lower portion including a first metal oxide or metal oxynitride, and an upper portion on the lower portion, the upper portion including a metal or a metal nitride, and wherein each of the first and third gate electrodes further includes tetravalent and pentavalent elements.

In a method of manufacturing a semiconductor device according to example implementations, a gate structure may be formed by sequentially stacking a gate dielectric pattern and a gate electrode, and a lower portion of the gate electrode may be doped with tetravalent and pentavalent elements. Thus, even if oxygen included in the gate dielectric pattern diffuses to form an oxidation region including a metal oxide or a metal oxynitride at the lower portion of the gate electrode, the tetravalent and pentavalent elements may be evenly distributed in the oxidation region, and a reduction of capacitance of the gate electrode due to the oxidation region may be prevented. Thus, the semiconductor device may have improved electrical characteristics.

### BRIEF DESCRIPTION OF THE DRAWINGS

FIG. 1 is cross-sectional view illustrating a semiconductor device in accordance with example implementations.

FIGS. 2 to 8 are cross-sectional views illustrating a method of manufacturing a semiconductor device according to example implementations.

FIG. 9 is a cross-sectional view illustrating a semiconductor device in accordance with example implementations.

FIGS. 10 and 11 are cross-sectional views illustrating a method of manufacturing semiconductor device in accordance with example implementations.

### DETAILED DESCRIPTION

The above and other aspects and features of the transistors and the methods of manufacturing the same, and the semiconductor devices including the transistors and the methods of manufacturing the same in accordance with example implementations will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

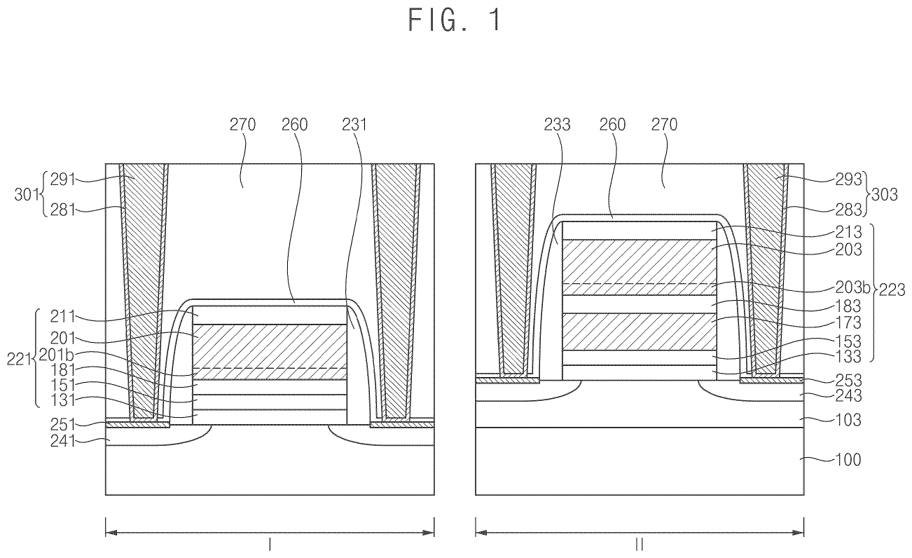

FIG. 1 is cross-sectional view illustrating a semiconductor device in accordance with example implementations.

Referring to FIG. 1, the semiconductor device may include a first transistor and a second transistor on a substrate 100.

The semiconductor device may also include an epitaxial layer 103, first and second gate spacers 231 and 233, first and second ohmic contact patterns 251 and 253, an etch stop layer 260, an insulating interlayer 270, and first and second contact plugs 301 and 303.

The substrate 100 may include a first region I and a second region II. The first and second regions I and II of the substrate 100 may be adjacent to each other or spaced apart from each other. In example implementations, the first region I may be an NMOS region where NMOS transistors are located, and the second region II may be an PMOS region where PMOS transistors are located.

An isolation pattern, which may insulate the first region I of the substrate 100 and the second region II of the substrate 100 from each other, may be disposed on the substrate 100. The isolation pattern may include, e.g., silicon oxide.

The substrate 100 may include a semiconductor material, e.g., silicon, silicon germanium, etc. A first well region doped with, e.g., p-type, impurities may be disposed in the first region I of the substrate 100, and a second well region doped with, e.g., n-type, impurities may be disposed in the second region II of the substrate 100.

In example implementations, based on a lower surface of the substrate 100, a height of an upper surface of the first region I of the substrate 100 may be substantially the same as a height of an upper surface in the second region II of the substrate 100.

The epitaxial layer 103 may be disposed on the second region II of the substrate 100. The epitaxial layer 103 may include a semiconductor material, e.g., germanium, silicon-germanium, etc. The epitaxial layer 103 may be doped with n-type impurities, and the epitaxial layer 103 together with the second region II of the substrate 100 may form the second well region.

In example implementations, based on the lower surface of the substrate 100, a height of an upper surface of the epitaxial layer 103 may be greater than the height of the upper surface in the first region I of the substrate 100.

The first transistor may be disposed on the first region I of the substrate 100. The first transistor may include a first gate structure 221 and a first source/drain region 241. The second transistor may be disposed on the second region II of the substrate 100. The second transistor may include a second gate structure 223 and a second source/drain region 243.

The first gate structure 221 may include a first gate interface pattern 131, a first gate dielectric pattern 151, a second gate dielectric pattern 181, a first gate electrode 201 and a first capping pattern 211 sequentially stacked on the first region I of the substrate 100.

The second gate structure 223 may include a second gate interface pattern 133, a third gate dielectric pattern 153, a second gate electrode 173, a fourth gate dielectric pattern 183, a third gate electrode 203 and a second capping pattern 213 sequentially stacked on the epitaxial layer 103 on the second region II of the substrate 100.

In example implementations, based on the lower surface of the substrate 100, a height of a lower surface and an upper surface of the second gate structure 223 may be greater than a height of a lower surface and an upper surface of the first gate structure 221, respectively.

The first and second gate interface patterns 131 and 133 may include substantially the same material, e.g., an oxide such as silicon oxide. The first gate interface pattern 131 may be disposed between the substrate 100 and the first gate dielectric pattern 151, and the second gate interface pattern 133 may be disposed between the substrate 100 and the third gate dielectric pattern 153. Thus, interface characteristics between the substrate 100 and each of the first and third gate dielectric patterns 151 and 153 may be improved, and hence, mobility of carriers may be improved.

Each of the first to fourth gate dielectric patterns 151, 181, 153 and 183 may include, e.g., a high-K dielectric material. The high-K dielectric material may refer to a material having a dielectric constant greater than a dielectric constant of silicon oxide (approximately 3.9), which is commonly used as a gate interface pattern.

Specifically, each of the first and third gate dielectric patterns 151 and 153 may include a metal oxide, e.g., hafnium oxide, zirconium oxide, lanthanum oxide, etc., a metal silicate, e.g., hafnium silicate (HfSiₓO_{y}), zirconium silicate (ZrSiₓO_{y}), etc., or a metal silicate nitride, e.g., hafnium silicate nitride (HfSiₓO_{y}N_{z}), zirconium silicate nitride (ZrSiₓO_{y}N_{z}).

Each of the second and fourth gate dielectric patterns 181 and 183 may include a metal oxide, e.g., hafnium oxide, zirconium oxide, lanthanum oxide, etc.

The first and third gate electrodes 201 and 203 may be disposed on the second and fourth gate dielectric patterns 181 and 183, respectively, and the second gate electrode 173 may be disposed between the fourth gate dielectric pattern 183 and the third gate dielectric pattern 153. Each of the first to third gate electrodes 201, 173 and 203 may include a metal, e.g., tungsten (W), or a metal nitride, e.g., titanium nitride (TiNₓ).

First and second oxide doping regions 201b and 203b may be disposed at lower portions of the first and third gate electrodes 201 and 203, respectively. Each of the first and second oxide doping regions 201b and 203b may include a metal oxide or a metal oxynitride doped with tetravalent and pentavalent elements. The metal oxide may include, e.g., tungsten oxide, and the metal oxynitride may include, e.g., titanium oxynitride.

The tetravalent element may include, e.g., at least one of, i.e., any combination of zirconium (Zr), hafnium (Hf), silicon (Si), germanium (Ge), and tin (Sn), among other tetravalent elements. The pentavalent element may include, e.g., at least one of, i.e., any combination of niobium (Nb), tantalum (Ta), vanadium (V), phosphorus (P), nitrogen (N), arsenic (As), antimony (Sb), among other pentavalent elements.

In example implementations, an oxygen areal density of the metal oxide or the metal oxynitride included in the first and second oxide doping regions 201b and 203b may be smaller than an oxygen areal density of the metal oxide included in the second and fourth gate dielectric patterns 181 and 183.

In example implementations, a thickness of each of the first and second oxide doping regions 201b and 203b may be about 10 Å, and a thickness of each of the first and third gate electrodes 201 and 203 may be about 40 Å to about 50 Å. That is, thicknesses of upper portions of the first and third gate electrodes 201 and 203 where the first and second oxide doping regions 201b and 203b are not disposed, respectively, may be about 3 times to about 4 times greater than thicknesses of the lower portions of the first and third gate electrodes 201 and 203 where the first and second oxide doping regions 201b and 203b are disposed, respectively.

The upper portion of each of the first and third gate electrodes 201 and 203 may also include the tetravalent and pentavalent elements. A concentration of each of the tetravalent and pentavalent elements included in the first gate electrode 201 may decrease along a vertical direction substantially perpendicular to an upper surface of the substrate 100 from a bottom surface toward a top surface of the first gate electrode 201. A concentration of each of the tetravalent and pentavalent elements included in the third gate electrode 203 may decrease along the vertical direction from a bottom surface toward a top surface of the third gate electrode 203.

The first and second capping patterns 211 and 213 may be disposed on the first and third gate electrodes 201 and 203, respectively, and may include the same material, e.g., an insulating nitride such as silicon nitride.

The first and second gate spacers 231 and 233 may cover sidewalls of the first and second gate structures 221 and 223, respectively. The first and second gate spacers 231 and 233 may include the same material, e.g., an oxide such as silicon oxide.

The first source/drain region 241 may be disposed at an upper portion of the first region I of the substrate 100 adjacent to the first gate structure 221. The first source/drain region 241 may include, e.g., n-type impurities. The second source/drain region 243 may be disposed at an upper portion of the epitaxial layer 103 adjacent to the second gate structure 223 on the second region II of the substrate 100. The second source/drain region 243 may include, e.g., p-type impurities.

FIG. 1. shows that a distance from a bottom surface of the second source/drain region 243 to the bottom surface of the substrate 100 is greater than a distance from the bottom surface of the epitaxial layer 103 to the bottom surface of the substrate 100, however, this disclosure is not limited thereto. That is, in some implementations, the distance from the bottom surface of the second source/drain region 243 to the bottom surface of the substrate 100 may be smaller than the distance from the bottom surface of the epitaxial layer 103 to the bottom surface of the substrate 100.

First and second ohmic contact patterns 251 and 253 may disposed on the first and second source/drain regions 241 and 243, respectively. Each of the first and second ohmic contact patterns 251 and 253 may include a metal silicide, e.g., titanium silicide, cobalt silicide, nickel silicide, etc.

The etch stop layer 260 may be conformally disposed on the first and second gate structures 221 and 223, the first and second gate spacers 231 and 233, and the first and second ohmic contact patterns 251 and 253. The insulating interlayer 270 may be disposed on the etch stop layer 260. The etch stop layer 260 may include a nitride, e.g., silicon nitride. The insulating interlayer 270 may include an oxide, e.g., silicon oxide.

The first contact plug 301 may extend through the insulating interlayer 270 and the etch stop layer 260 on the first region I of the substrate 100 to contact an upper surface of the first ohmic contact pattern 251. The first contact plug 301 may include a first conductive pattern 291 and a first barrier pattern 281 covering a sidewall and a lower surface thereof.

The second contact plug 303 may extend through the insulating interlayer 270 and the etch stop layer 260 on the second region II of the substrate 100 to contact an upper surface of the second ohmic contact pattern 253. The second contact plug 303 may include a second conductive pattern 293 and a second barrier pattern 283 covering a sidewall and a lower surface thereof.

Each of the first and second conductive patterns 291 and 293 may include a metal, e.g., tungsten. Each of the first and second barrier patterns 281 and 283 may include a metal nitride, e.g., titanium nitride.

As illustrated above, the first gate structure 221 may include the second gate dielectric pattern 181 and the first gate electrode 201 sequentially stacked, and the second gate structure 223 may include the fourth gate dielectric pattern 183 and the third gate electrode 203 sequentially stacked.

Each of the second and fourth gate dielectric patterns 181 and 183 may include a metal oxide, and each of the first and third gate electrodes 201 and 203 may include a metal or a metal nitride, and as illustrated below, during a process of forming the first and third electrodes 201 and 203, oxygen included in the second and fourth gate dielectric patterns 181 and 183 may be diffused, so that the first and second oxide doping regions 201b and 203b including a metal oxide or a metal oxynitride may be formed, respectively, at lower portions of the first and third gate electrodes 201 and 203.

The metal oxide or the metal oxynitride included in the first and second oxide doping regions 201b and 203b may reduce the capacitance of the first and third gate electrodes 201 and 203, respectively. However, the pentavalent element may be doped into the first and second oxide doping regions 201b and 203b to prevent such reduction of the capacitance. In particular, not only the pentavalent element but also the tetravalent element may be doped into the first and second oxide doping regions 201b and 203b so that the pentavalent element may be evenly distributed in the first and second oxide doping regions 201b and 203b, and thus prevent the reduction of the capacitance of the first and third gate electrodes 201 and 203.

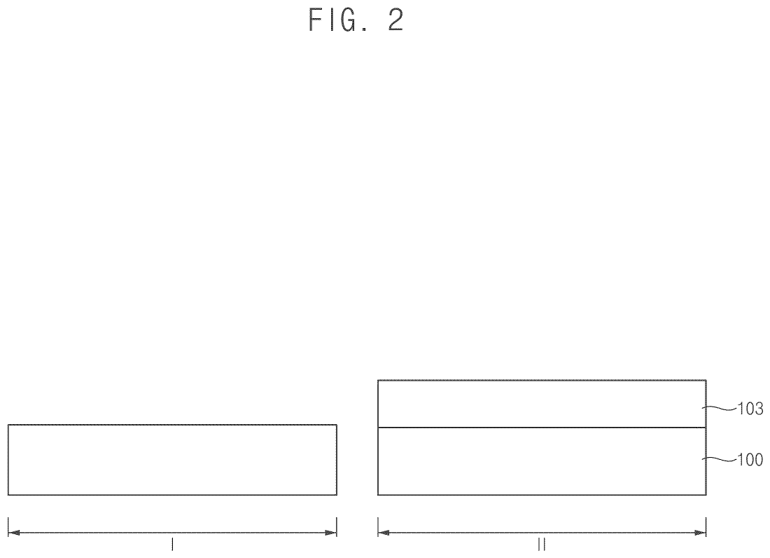

FIGS. 2 to 8 are cross-sectional views illustrating a method of manufacturing a semiconductor device according to example implementations.

Referring to FIG. 2, after forming a first mask that may cover an upper surface of a first region I of a substrate 100 and expose an upper surface of a second region II of the substrate 100, an epitaxial growth process may be performed on the exposed upper surface of the second region II of the substrate 100 to form an epitaxial layer 103.

In example implementations, the substrate 100 may include a semiconductor material, e.g., silicon, germanium, silicon-germanium, etc., and the substrate 100 may be a p-type semiconductor substrate including a first well doped with p-type impurities.

The epitaxial layer 103 may include a semiconductor material, e.g., germanium, silicon-germanium, etc. In example implementations, an upper surface of the epitaxial layer 103 may be formed to be higher than the upper surface of the first region I of the substrate 100.

An ion implantation process may be performed on the second region II of the substrate 100 and the epitaxial layer 103 using n-type impurities. Thus, a second well region including a semiconductor material doped with n-type impurities may be formed in the second region II of the substrate 100 and the epitaxial layer 103.

The first mask may be removed.

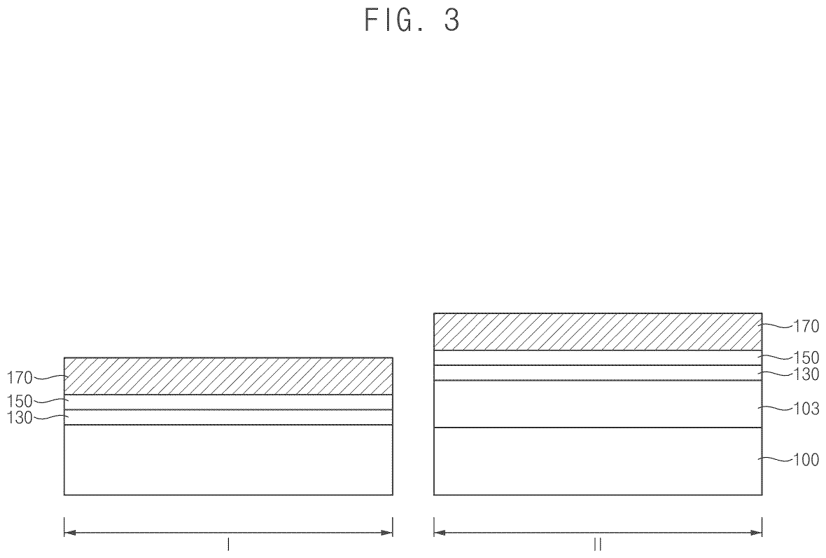

Referring to FIG. 3, a gate interface layer 130 and a first gate dielectric layer 150 may be sequentially formed on the substrate 100 and the epitaxial layer 103.

The gate interface layer 130 may include an oxide, e.g., silicon oxide. The first gate dielectric layer 150 may include a high-K dielectric material having a dielectric constant greater than a dielectric constant of silicon oxide (approximately 3.9).

A first gate electrode layer 170 may be formed on the first gate dielectric layer 150.

In example implementations, each of the gate interface layer 130, the first gate dielectric layer 150 and the first gate electrode layer 170 may be formed by, e.g., a chemical vapor deposition (CVD) process, a low-pressure CVD (LPCVD) process, a plasma-enhanced CVD (PECVD) process, a metal-organic CVD (MOCVD) process, an atomic layer deposition (ALD), a plasma-enhanced ALD (PEALD) process, etc.

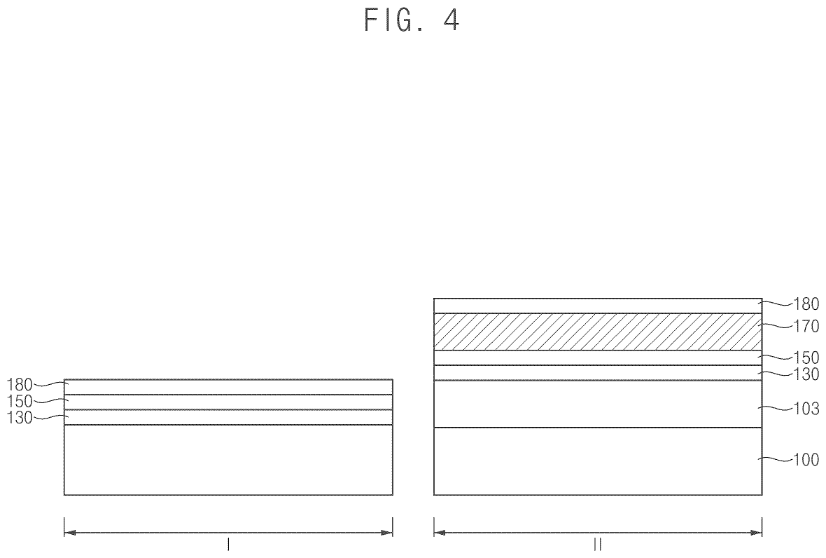

Referring to FIG. 4, after forming a second mask that may cover a portion of the first gate electrode layer 170 on the second region II of the substrate 100 and expose a portion of the first gate electrode layer 170 on the first region I of the substrate 100, the exposed portion of the first gate electrode layer 170 on the second region II of the substrate 100 may be removed by performing, e.g., an etching process, and thus a portion of the first gate dielectric layer 150 on the first region I of the substrate 100 may be exposed.

The second mask may be removed to expose the portion of the first gate electrode layer 170 on the second region II of the substrate 100, and a second gate dielectric layer 180 may be formed on the exposed portion of the first gate dielectric layer 150 and the first gate electrode layer 170.

The second gate dielectric layer 180 may include a high-K dielectric material having a dielectric constant greater than the dielectric constant of silicon oxide (approximately 3.9). Specifically, the second gate dielectric layer 180 may include a metal oxide, e.g., hafnium oxide, zirconium oxide, lanthanum oxide, etc.

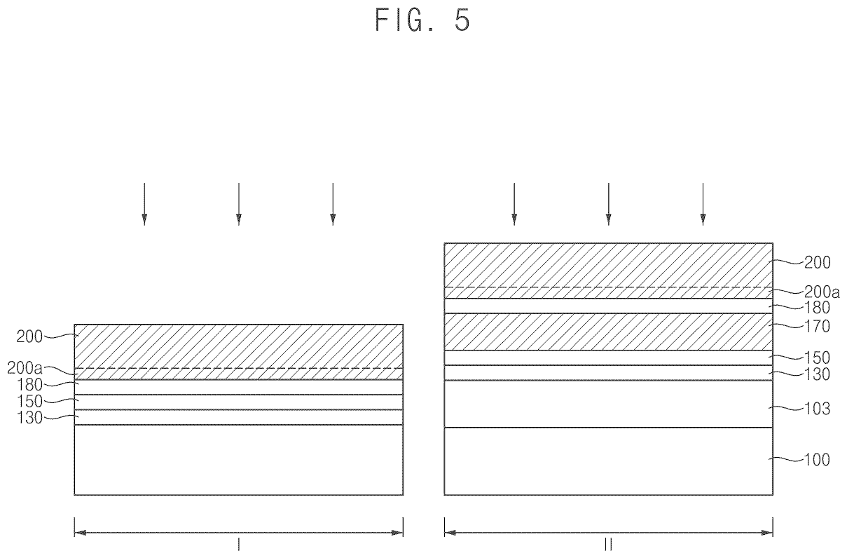

Referring to FIG. 5, a second gate electrode layer 200 may be formed on the second gate dielectric layer 180, an ion implantation process in which the second gate electrode layer 200 is doped with tetravalent and pentavalent elements may be performed, and thus, a doping region 200a may be formed at a lower portion of the second gate electrode layer 200.

In example implementations, the second gate electrode layer 200 may include a metal, e.g., tungsten (W), titanium (Ti), or a metal nitride, e.g., titanium nitride (TiNₓ).

The ion implantation process may be performed by sequentially or simultaneously implanting the tetravalent and pentavalent elements, and the tetravalent and pentavalent elements may also be doped at a relatively low concentration in an upper portion of the second gate electrode layer 200. That is, a concentration of each of the tetravalent and pentavalent elements may decrease along a vertical direction substantially perpendicular to an upper surface of the substrate 100 from a lower surface toward an upper surface of the second gate electrode layer 200.

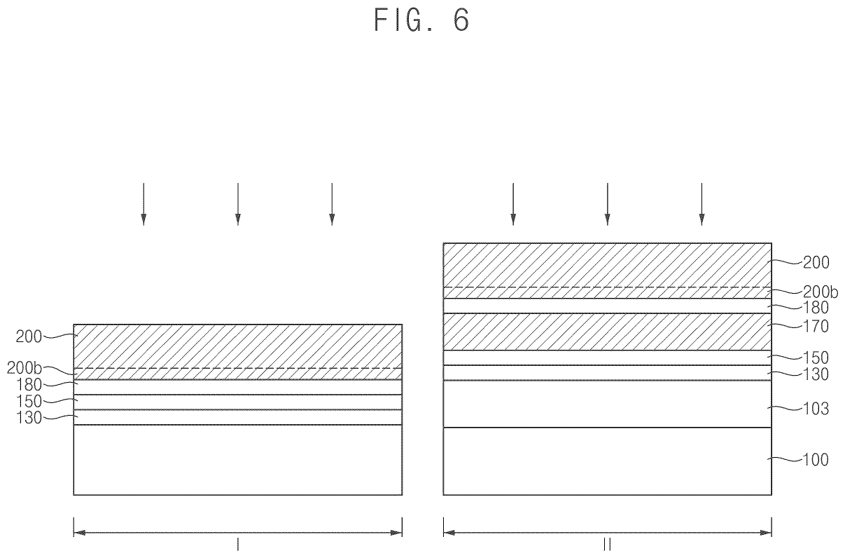

Referring to FIG. 6, an annealing process may be performed on the second gate electrode layer 200, and thus, the tetravalent and pentavalent elements doped in the second gate electrode layer 200 may diffuse in a horizontal direction substantially parallel to the upper surface of the substrate 100 to be evenly distributed in the lower portion of the second gate electrode layer 200.

The doping region 200a may be formed in the lower portion of the second gate electrode layer 200 adjacent to an upper surface of the second gate dielectric layer 180, so that oxygen may diffuse from the metal oxide included in the second gate dielectric layer 180, and thus the doping region 200a may be converted into an oxide doping region 200b including a metal oxide or a metal oxynitride.

The oxide doping region 200b may be formed by the diffusion of oxygen included in the second gate dielectric layer 180, so that an oxygen areal density of the metal oxide or metal oxynitride included in the oxide doping region 200b may be lower than an oxygen areal density of the metal oxide included in the second gate dielectric layer 180.

Hereinafter, portions of the gate interface layer 130, the first gate dielectric layer 150 and the second gate electrode layer 200 on the first region I of the substrate 100 are collectively referred to as a first gate layer structure, and portions of the gate interface layer 130, the first gate dielectric layer 150, the first gate electrode layer 170, the second gate dielectric layer 180 and the second gate electrode layer 200 on the second region II of the substrate 100 are collectively referred to as the second gate layer structure.

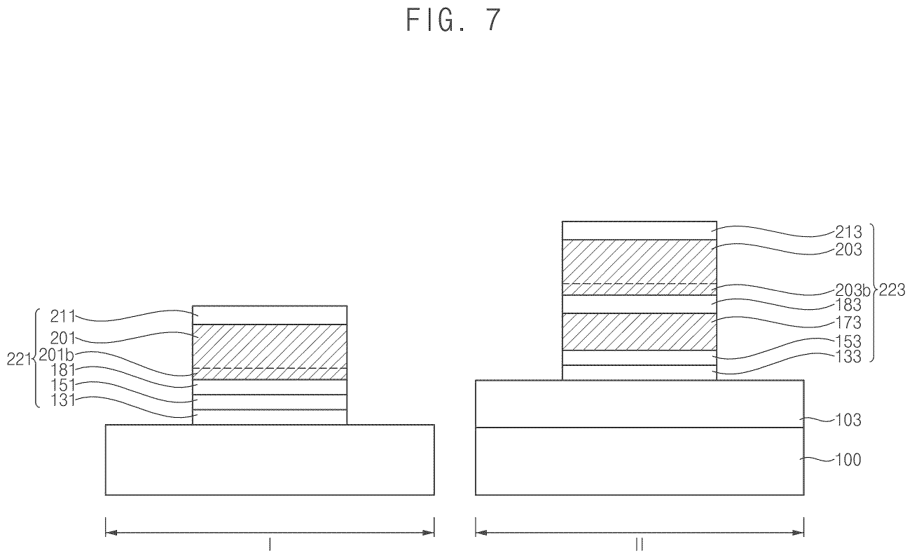

Referring to FIG. 7, first and second capping patterns 211 and 213 may be formed on the first and second gate layer structures, respectively, and an etching process using the first and second capping patterns 211 and 213 as an etching mask may be performed to pattern the first and second gate layer structures.

Thus, portions of the gate interface layer 130, the first gate dielectric layer 150, the second gate dielectric layer 180 and the second gate electrode layer 200 sequentially stacked on the first region I of the substrate 100 may be transformed into a first gate interface pattern 131, a first gate dielectric pattern 151, a second gate dielectric pattern 181 and a first gate electrode 201, respectively, and portions of the gate interface layer 130, the first gate dielectric layer 150, the first gate electrode layer 170, the second gate dielectric layer 180 and the second gate electrode layer 200 sequentially stacked on the epitaxial layer 103 on the second region II of the substrate 100 may be transformed into a second gate interface pattern 133, a third gate dielectric pattern 153, a second gate electrode 173, a fourth gate dielectric pattern 183 and a third gate electrode 203, respectively.

The first and third gate electrodes 201 and 203 may include first and second oxide doping regions 201b and 203b, respectively, at lower portions thereof, corresponding to the oxide doping region 200b of the second gate electrode layer 200.

In example implementations, both of the first and second gate interface patterns 131 and 133 may be formed from the gate interface layer 130 so as to include substantially the same material, both of the first and third gate dielectric patterns 151 and 153 may be formed from the first gate dielectric layer 150 so as to include substantially the same material, and both of the second and fourth gate dielectric patterns 181 and 183 may be formed from the second gate dielectric layer 180 so as to include substantially the same material.

The first gate interface pattern 131, the first gate dielectric pattern 151, the second gate dielectric pattern 181, the first gate electrode 201 and the first capping pattern 211 sequentially stacked on the first region I of the substrate 100 may collectively form a first gate structure 221. The second gate interface pattern 133, the third gate dielectric pattern 153, the second gate electrode 173, the fourth gate dielectric pattern 183, the third gate electrode 203 and the second capping pattern 213 sequentially stacked on the epitaxial layer 103 on the second region II of the substrate 100 may collectively form a second gate structure 223.

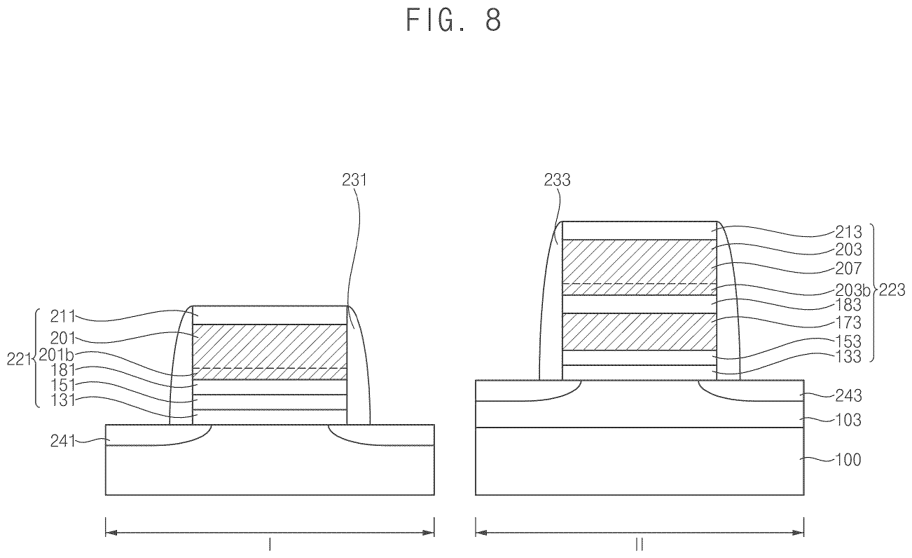

Referring to FIG. 8, a gate spacer layer may be, e.g., conformally formed on the upper surface of the substrate 100, the upper surface of the epitaxial layer 103, a sidewall and an upper surface of the first gate structure 221 and a sidewall and an upper surface of the second gate structure 223, and an anisotropic etching process may be performed on the gate spacer layer to form first and second gate spacers 231 and 233 that may cover the sidewall of the first and second gate structures 221 and 223, respectively.

A first ion implantation process may be performed on an upper portion of the first region I of the substrate 100 adjacent to the first gate structure 221 to form a first source/drain region 241, and a second ion implantation process may be performed on an upper portion of the epitaxial layer 103 adjacent to the second gate structure 223 to form a second source/drain region 243. In example implementations, the first source/drain region 241 may include n-type impurities, and the second source/drain region 243 may include p-type impurities.

The first gate structure 221 and the first source/drain region 241 may collectively form a first transistor, and the second gate structure 223 and the second source/drain region 243 may collectively form a second transistor. In example implementations, the first transistor may be an NMOS transistor, and the second transistor may be a PMOS transistor.

Referring back to FIG. 1, first and second ohmic contact patterns 251 and 253 may be formed on upper surfaces of the first and second source/drain regions 241 and 243, respectively.

In example implementations, the first and second ohmic contact patterns 251 and 253 may be formed by forming a metal layer on the first and second gate structures 221 and 223, the first and second gate spacers 231 and 233, and the first and second source/drain regions 241 and 243, performing a heat treatment on the metal layer, and removing an unreacted portion of the metal layer.

An etch stop layer 260 and an insulating interlayer 270 may be sequentially formed on the first and second ohmic contact patterns 251 and 253, the first and second gate spacers 231 and 233, and the first and second gate structures 221 and 223.

A first opening may be formed through the insulating interlayer 270 and the etch stop layer 260 on the first region I of the substrate 100 to expose an upper surface of the first ohmic contact pattern 251, and a first contact plug 301 may be formed in the first opening. A second opening may be formed through the insulating interlayer 270 and the etch stop layer 260 on the second region II of the substrate 100 to expose an upper surface of the second ohmic contact pattern 253, and a second contact plug 303 may be formed in the second opening.

In example implementations, the first contact plug 301 may include a first conductive pattern 291 and a first barrier pattern 281 covering a sidewall and a lower surface thereof, and the second contact plug 303 may include a second conductive pattern 293 and a second barrier pattern 283 covering a sidewall and a lower surface thereof.

Manufacturing of the semiconductor device may be completed by forming contact plugs and wirings electrically connected to various structures on the substrate 100.

In the method of manufacturing the semiconductor device, the second gate dielectric layer 180 including a metal oxide may be formed, and the second gate electrode layer 200 including a metal or a metal nitride may be formed on the second gate dielectric layer 180. An ion implantation process may be performed on the second gate electrode layer 200 to form the doping region 200a including the tetravalent and pentavalent elements at the lower portion of the second gate electrode layer 200, and an annealing process may be performed on the second gate electrode layer 200 to convert the doping region 200a into the oxide doping region 200b including a metal oxide or a metal oxynitride.

If the ion implantation process is not performed on the second gate electrode layer 200, the oxygen included in the second gate dielectric layer 180 may diffuse to be combined with the metal or the metal nitride included in the second gate electrode layer 200, so that a metal oxide or a metal oxynitride may be formed, which may reduce a capacitance of the second gate electrode layer 200.

Additionally, if the pentavalent element only is doped into the second gate electrode layer 200 by the ion implantation process, the reduction of the capacitance of the second gate electrode layer 200 may be prevented compared to a case in which the ion implantation process is not performed, however if a concentration of the pentavalent element exceeds a certain level, the pentavalent element may not be evenly distributed in the metal oxide or metal oxynitride, which may limit an increase of the capacitance.

However, in example implementations, the second gate electrode layer 200 may be doped with not only the pentavalent element but also with the tetravalent element by the ion implantation process. Thus, the pentavalent element may be evenly distributed in the oxide doping region 200b at the lower portion of the second gate electrode layer 200, and thus the reduction of the capacitance of the second gate electrode layer 200 may be prevented.

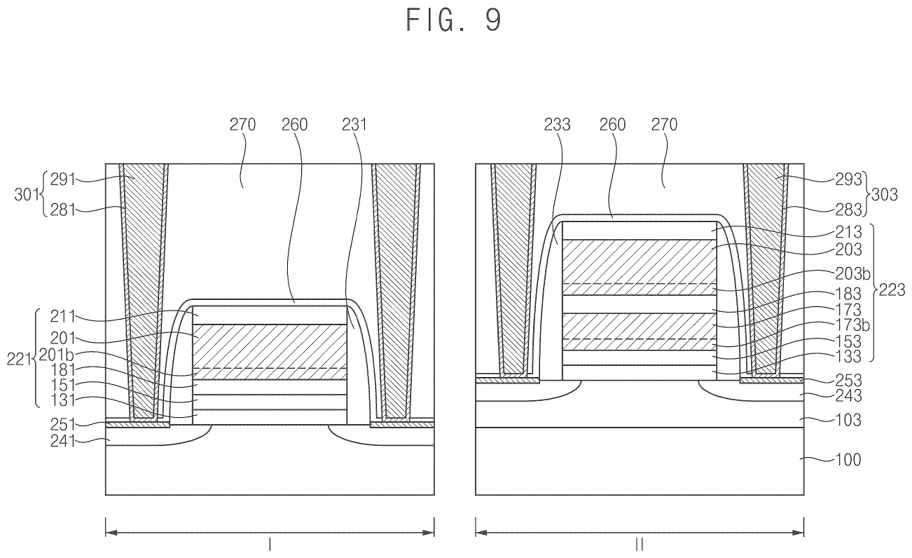

FIG. 9 is a cross-sectional view illustrating a semiconductor device in accordance with example implementations, corresponding to FIG. 1. The semiconductor device may be substantially the same as or similar to a semiconductor device of FIG. 1, except for the second gate electrode 173, and thus repeated explanations are omitted herein.

Referring to FIG. 9, a third oxide doping region 173b may be disposed at a lower portion of the second gate electrode 173.

The third oxide doping region 173b may include a metal oxide or a metal oxynitride doped with tetravalent and pentavalent elements. The metal oxide may include, e.g., tungsten oxide, and the metal oxynitride may include, e.g., titanium oxynitride. The tetravalent element may include, e.g., at least one of, i.e., any combination of zirconium (Zr), hafnium (Hf), silicon (Si), germanium (Ge), and tin (Sn), among other tetravalent elements. The pentavalent element may include, e.g., at least one of, i.e., any combination of, niobium (Nb), tantalum (Ta), vanadium (V), phosphorus (P), nitrogen (N), arsenic (As), and antimony (Sb), among other pentavalent elements.

In example implementations, an oxygen areal density of the metal oxide or the metal oxynitride included in the third oxide doping region 173b may be smaller than an oxygen areal density of the metal oxide included in the third gate dielectric pattern 153.

The tetravalent and pentavalent elements may also be included in an upper portion of the second gate electrode 173. A concentration of each of the tetravalent and pentavalent elements included in the second gate electrode 173 may decrease in the vertical direction from a lower surface toward an upper surface of the second gate electrode 173.

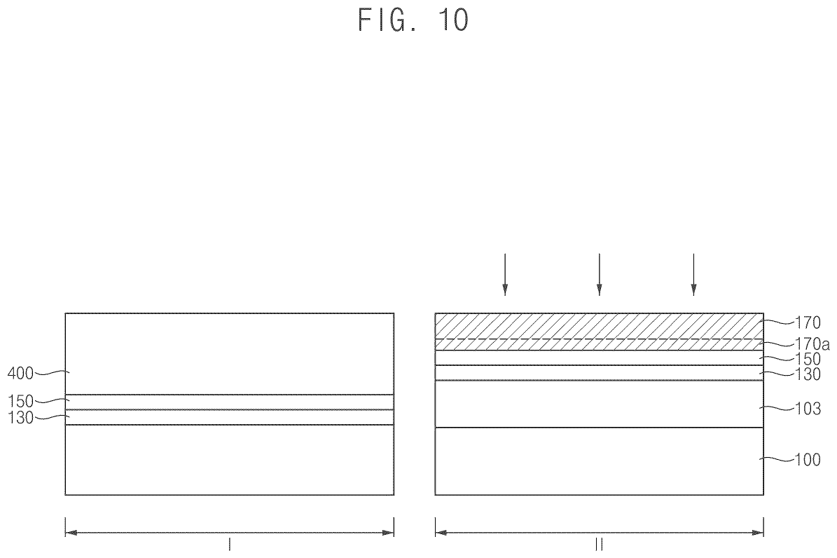

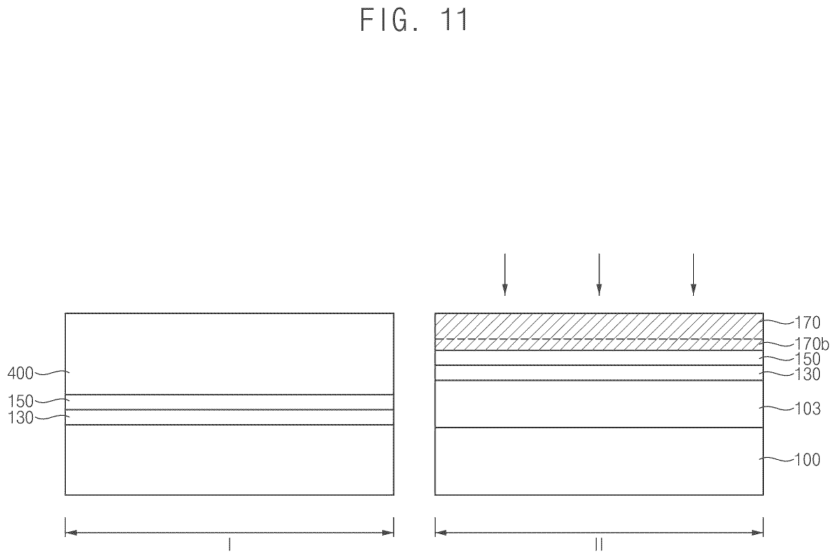

FIGS. 10 and 11 are cross-sectional views illustrating a method of manufacturing a semiconductor device in accordance with example implementations. This method may include processes substantially the same as or similar to those illustrated with reference to FIGS. 2 to 8 and 1, and thus repeated explanations thereof are omitted herein.

Referring to FIG. 10, after performing processes substantially the same as or similar to the processes illustrated with reference to FIGS. 2 and 3, a portion of the first gate electrode layer 170 on the first region I of the substrate 100 may be removed to expose a portion of the first gate dielectric layer 150 on the first region I of the substrate 100.

A third mask 400 that may cover the exposed portion of the first gate dielectric layer 150 and expose the first gate electrode layer 170 on the second region II of the substrate 100 may be formed on the first region I of the substrate 100, and an ion implantation process for doping the exposed first gate electrode layer 170 with tetravalent and pentavalent elements may be performed, and thus a doping region 170a may be formed at a lower portion of the first gate electrode layer 170.

The ion implantation process may be performed by sequentially or simultaneously implanting the tetravalent element and the pentavalent element, and the tetravalent and pentavalent elements may also be doped at a relatively low concentration into an upper portion of the first gate electrode layer 170. That is, a concentration of each of the tetravalent and pentavalent elements may decrease in the vertical direction from a lower surface toward an upper surface of the first gate electrode layer 170.

Referring to FIG. 11, an annealing process may be performed on the first gate electrode layer 170, and thus, the tetravalent and pentavalent elements doped in the first gate electrode layer 170 may diffuse in the horizontal direction to be evenly distributed in the lower portion of the first gate electrode layer 170.

The doping region 170a may be formed at the lower portion of the first gate electrode layer 170 adjacent to the upper surface of the first gate dielectric layer 150, so that oxygen may diffuse from the metal oxide included in the first gate dielectric layer 150, and thus, the doping region 170a may be converted into an oxide doping region 170b including a metal oxide or a metal oxynitride.

The oxide doping region 170b may be formed by diffusion of oxygen from the oxide included in the first gate dielectric layer 150, so that an oxygen areal density of the metal oxide or the metal oxynitride included in the oxide doping region 170b may be lower than an oxygen areal density of the metal oxide included in the first gate dielectric layer 150.

The third mask 300 may be removed, and manufacturing of the semiconductor device may be completed by performing processes substantially the same as or similar to the processes illustrated with reference to FIGS. 2 to 8 and FIG. 1.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to example implementations thereof, it will be understood by those of ordinary skill in the art that various changes in form and details may be made thereto without departing from the spirit and scope as set forth by the following claims.

What is claimed is:

1. A transistor comprising:
a gate structure on a substrate, the gate structure including:
a first gate dielectric pattern including a first metal oxide;
a gate electrode comprising:
a lower portion including a second metal oxide doped with tetravalent and pentavalent elements or a metal oxynitride doped with the tetravalent and pentavalent elements; and
an upper portion on the lower portion including a metal doped with the tetravalent and pentavalent elements or a metal nitride doped with the tetravalent and pentavalent elements; and
a source/drain region at an upper portion of the substrate adjacent to the gate structure.

2. The transistor of claim 1, wherein the metal in the upper portion of the gate electrode is the same as the metal in the second metal oxide or the metal oxynitride of the lower portion of the gate electrode.

3. The transistor of claim 2, wherein a concentration of the tetravalent and pentavalent elements in the lower portion of the gate electrode is higher than a concentration of the tetravalent and pentavalent elements in the upper portion of the gate electrode.

4. The transistor of claim 1, wherein the tetravalent element comprises at least one of zirconium (Zr), hafnium (Hf), silicon (Si), germanium (Ge), and tin (Sn), and the pentavalent element comprises at least one of niobium (Nb), tantalum (Ta), vanadium (V), phosphorus (P), nitrogen (N), arsenic (As), and antimony (Sb).

5. The transistor of claim 1, wherein an oxygen areal density of the second metal oxide or the metal oxynitride included in the gate electrode is lower than an oxygen areal density of the first metal oxide.

6. The transistor of claim 1, further comprising a gate interface pattern and a second gate dielectric pattern sequentially stacked on the substrate, wherein:
the first gate dielectric pattern is on the second gate dielectric pattern,
the gate interface pattern includes silicon oxide, and
the second gate dielectric pattern includes a high-K material.

7. The transistor of claim 1, further comprising a gate interface pattern, a second gate dielectric pattern and a second gate electrode sequentially stacked on the substrate, wherein:
the gate electrode is a first gate electrode, the metal is a first metal, and the metal nitride is
a first metal nitride,
the first gate dielectric pattern is on the second gate electrode,
the gate interface pattern includes silicon oxide,
the second gate dielectric pattern includes a high-K material, and
the second gate electrode includes a second metal or a second metal nitride.

8. The transistor of claim 7, wherein the second gate electrode includes:
a lower portion on the second gate dielectric pattern, the lower portion including a third metal oxide doped with the tetravalent and pentavalent elements; and
an upper portion on the lower portion, the upper portion including the second metal or the second metal nitride doped with the tetravalent and pentavalent elements.

9. A transistor comprising:
a gate structure including a gate interface pattern, a first gate dielectric pattern, a second gate dielectric pattern and a gate electrode sequentially stacked on a substrate; and
a source/drain region at an upper portion of the substrate adjacent to the gate structure, wherein:
the gate interface pattern includes silicon oxide,
each of the first and second gate dielectric patterns includes a high-K material,
the gate electrode includes a metal or a metal nitride doped with tetravalent and pentavalent elements, and
a concentration of the tetravalent and pentavalent elements in the gate electrode decreases along a vertical direction substantially perpendicular to an upper surface of the substrate as a distance from the upper surface of the substrate increases.

10. The transistor of claim 9, wherein each of the first and second gate dielectric patterns includes a first metal oxide.

11. The transistor of claim 10, wherein the gate electrode includes:
a lower portion including a second metal oxide; and
an upper portion on the lower portion, the upper portion including a metal included in the lower portion or a metal nitride of the metal included in the lower portion.

12. The transistor of claim 11, wherein an oxygen areal density of the second metal oxide included in the lower portion of the gate electrode is lower than an oxygen areal density of the first metal oxide included in the second gate dielectric pattern.

13. The transistor of claim 11, wherein a thickness of the upper portion of the gate electrode is three times to four times a thickness of the lower portion of the gate electrode.

14. The transistor of claim 9, wherein the tetravalent element includes at least one of zirconium (Zr), hafnium (Hf), silicon (Si), germanium (Ge), and tin (Sn), and the pentavalent element includes at least one of niobium (Nb), tantalum (Ta), vanadium (V), phosphorus (P), nitrogen (N), arsenic (As), and antimony (Sb).

15. A semiconductor device comprising:
a first transistor including:
a first gate structure including a first gate interface pattern, a first gate dielectric pattern and a first gate electrode sequentially stacked on a first region of a substrate including the first region and a second region; and
a first source/drain region at an upper portion of the substrate adjacent to the first gate structure;
an epitaxial layer on the second region of the substrate; and
a second transistor including:
a second gate structure including a second gate interface pattern, a second gate dielectric pattern, a second gate electrode, a third gate dielectric pattern and a third gate electrode sequentially stacked on the epitaxial layer; and
a second source/drain region at an upper portion of the epitaxial layer adjacent to the second gate structure,
wherein each of the first and third gate electrodes includes:
a lower portion including a first metal oxide or metal oxynitride, and
an upper portion on the lower portion, the upper portion including a metal or a metal nitride, and
wherein each of the first and third gate electrodes further includes tetravalent and pentavalent elements.

16. The semiconductor device of claim 15, wherein the first transistor is an NMOS transistor and the second transistor is a PMOS transistor.

17. The semiconductor device of claim 15, wherein the epitaxial layer includes germanium or silicon-germanium.

18. The semiconductor device of claim 15, wherein a concentration of each of the tetravalent and pentavalent elements in the lower portion of each of the first and third gate electrodes is higher than a concentration of each of the tetravalent and pentavalent elements in the upper portion of each of the first and third gate electrodes.

19. The semiconductor device of claim 15, wherein the metal is a first metal, and the metal nitride is a first metal nitride, and
wherein the second gate electrode includes:
a lower portion including a second metal oxide; and
an upper portion on the lower portion, the upper portion including a second metal or a second metal nitride,
wherein the second gate electrode further includes tetravalent and pentavalent elements, and
wherein a concentration of each of the tetravalent and pentavalent elements in the lower portion of the second gate electrode is higher than a concentration of each of the tetravalent and pentavalent elements in the upper portion of the second gate electrode.

20. The semiconductor device of claim 15, wherein the lower portion and the upper portion of each of the first and third gate electrodes include the same metal.
